(19) United States
(12) Patent Application Publication
(10) Pub. No.: US 2025/0138080 A1
(43) Pub. Date: May 1, 2025

(54) EVALUATION METHOD OF METAL CONTAMINATION

(71) Applicant: GLOBALWAFERS JAPAN CO., LTD., Kitakanbara-gun (JP)

(72) Inventors: Takahiro MAETA, Kitakanbara-gun (JP); Haruo SUDO, Kitakanbara-gun (JP)

(73) Assignee: GLOBALWAFERS JAPAN CO., LTD., Kitakanbara-gun (JP)

(21) Appl. No.: 18/910,672

(22) Filed: Oct. 9, 2024

(30) Foreign Application Priority Data
Oct. 31, 2023 (JP) 2023-186997

(51) Int. Cl. G01R 31/28

(52) U.S. Cl. CPC G01R 31/2831

(57) ABSTRACT

A method of accurately evaluating the metal contamination on silicon wafers by lifetime measurement. The silicon wafers are subjected to heat treatment and further to a corona charge as passivation, and then, the lifetime is measured, in which the heat treatment is at least one of the following processes that the silicon wafer is held at a temperature of 1250° C. or more to 1330° C. or less for 7 s or more to 220 s or less under an oxygen atmosphere and then the temperature is lowered at a rate of 30° C./s or more to 500° C./s or less, or that and the silicon wafer is held at a temperature of 1020° C. or more to less than 1250° C. for 7 s or more to 600 s or less under an oxygen atmosphere, and then the temperature is lowered at a rate of 1° C./s or more to 280° C./s or less.

### BACKGROUND OF THE INVENTION

### Technical Field

The present invention relates to evaluation methods of metal contamination, for example, to an evaluation method of metal contamination using lifetime measurement of a silicon wafer having a surface with an oxide film formed thereon by heat treatment.

### Background Art

Metal impurities present in a silicon wafer form a deep energy level in a band gap (forbidden band). The deep energy level is energetically separated from a conduction band and a valence band. Electrons in the conduction band and holes in the valence band can be recombined at the deep energy level as an intermediate state. For example, even when the electrons or holes are provided by doping, the electrons or holes are annihilated by recombination at the deep energy level. That is, the deep energy level inhibits doping and largely affects the characteristics and reliability of a semiconductor device such as a transistor.

Accordingly, a proper evaluation of metal contamination of a silicon wafer is required in the manufacturing process of a semiconductor device.

A widely used method for evaluating the metal contamination of a silicon wafer is to measure the lifetime. The lifetime measurement of the silicon wafer is the measurement of the time until excited minority carriers are annihilated. In order to detect an extremely low level of metal contamination, higher sensitivity is required for the lifetime measurement.

One method of lifetime measurement with higher sensitivity is a microwave photoconductivity decay method (hereinafter, referred to as “μ-PCD method”) using laser and microwave. It is known that the lifetime measured by the μ-PCD method is sensitive to even small amounts of heavy metal contamination and defects.

In the μ-PCD method, excess carriers (electron-hole pairs) are generated by pulsed irradiation of a silicon wafer with an excited laser beam. The excess carriers are diffused, recombined, and annihilated. The time for the resistivity to return to the initial state by recombination of the excess carriers is measured from the microwave reflectivity, and the time for the minority carriers to recombine is defined as a lifetime. Note that the larger the amount of heavy metal mixed in the silicon wafer, the faster the recombination of excess carriers and the shorter the lifetime.

In the manufacture of the semiconductor device, heat treatment may be applied to the silicon wafer mainly for the recovery of ion implantation damage, electrical activation of implanted impurities, or the like. In the case of activation of implanted impurities, in long-term heat treatment, an impurity distribution is deformed and the junction becomes deeper due to thermal diffusion. To prevent this, a short-term heat treatment is required, but to ensure a certain activation rate, the heat treatment should be performed at a higher temperature. Accordingly, a single-wafer RTP (Rapid Thermal Process) apparatus is often used for heat treatment at high temperatures (for example, from 1000° C. to 1150° C.) in a short time of about 1 s by irradiation with a halogen lamp.

However, in an oxide film formed on a silicon wafer surface by heat treatment under an oxygen atmosphere in the RTP apparatus, which is referred to as an “RTO film”, recombination centers with higher density are present at the interface with silicon. When excess carriers (electron-hole pairs) are implanted in the silicon wafer surface with the RTO film formed thereon by pulse irradiation with the excited laser beam by the μ-PCD method, the excess carriers are annihilated mainly in the interface due to the existence of the recombination centers in the interface between the RTO film and the silicon.

That is, since the excess carriers do not reach the bulk region of the silicon wafer, it is difficult to simply apply the μ-PCD method which measures the time using the microwave reflectivity until the resistivity returns to the initial state by recombination of the excess carriers to the lifetime measurement of the bulk.

NPL 1 discloses a method for corona charging as pretreatment in the lifetime measurement of the silicon wafer with the RTO film formed thereon.

In this method, on the silicon wafer with the RTO film formed thereon, ions generated by corona discharge are deposited on the oxide film (RTO film) and the carriers near the interface are confined to the bulk. When the laser is irradiated on the corona-charged silicon wafer by the μ-PCD method, minority carriers or majority carriers no longer exist in the interface due to the polarity of the ions, and the lifetime of the bulk can be measured even when the RTO film is formed.

As an example employing the method of corona charging the silicon wafer with the RTO film formed thereon, the applicant of this application proposes an evaluation method of metal contamination of forming an RTO film on a silicon wafer, deactivating the surface by corona charging, and then, performing lifetime measurement in PTL 1. In the evaluation method of metal contamination, a metal contamination condition of an RTP apparatus is evaluated by using a wafer sliced from a predetermined region of an ingot (a region excluding parts up to 40 mm from the head of a single crystal toward the center and 40 mm from a tail (rear end portion) toward the center) formed by crystal growth under a predetermined growth condition. That is, the evaluation method of metal contamination is to reduce crystal defects of a silicon single crystal for easier detection of metal contamination of a silicon wafer and to evaluate metal contamination of the RTP apparatus with higher sensitivity.

### CITATION LIST

### Patent Literature

PTL 1: JP-A-2019-114633

### Non Patent Literature

NPL 1: Sumie, S and Takamatsu, H: “Detection of Heavy Metal Contamination in Semiconductor Processes Using a Carrier Lifetime Measurement System”, R&D KOBE STEEL ENGINEERING REPORTS, Vol. 52, No. 2 (September 2002), pp. 87-93.

### SUMMARY OF INVENTION

### Technical Problems

As described above, when performing the lifetime measurement using the μ-PCD method on the silicon wafer with the RTO film formed thereon, it is effective to perform corona charging as a pretreatment.

However, there is a problem that even by corona charging the silicon wafer with the RTO film formed thereon as pretreatment and measuring the lifetime by the μ-PCD method, if the metal contamination of the silicon wafer is contamination with a metal that does not affect the lifetime as a single atom by itself, the contamination cannot be detected.

In addition, the silicon wafers sometimes have crystal defects, which affect the lifetime measurement as noise that acts on the time for the excess carriers to recombine, making it impossible to measure the lifetime with high accuracy.

The method disclosed in PTL 1 is intended for the management of metal contamination of the RTP apparatus, and sufficient sensitivity cannot be obtained for the metal contamination evaluation of the silicon wafer with the RTO film formed thereon and the problems described above cannot be solved.

The inventors of this application made earnest study of the problems, and found that the problems described above can be solved by appropriately adjusting the condition of the RTO film before corona charging according to the metal contamination condition of the silicon wafer, and achieved the invention.

An object of the invention is to provide an evaluation method of metal contamination that enables a highly accurate evaluation of an amount of metal contamination on a silicon wafer by lifetime measurement.

### Solution to Problems

An evaluation method of metal contamination according to the invention, which has been achieved to solve the problems described above, is a method of evaluating metal contamination for a silicon wafer that is subjected to heat treatment and further subjected to corona charging as passivation, and then, the lifetime is measured; the heat treatment is at least one of the treatment processes that the silicon wafer is held at a temperature of 1250° C. or more to 1330° C. or less for 7 s or more to 220 s or less under an oxygen atmosphere and then the temperature is lowered at a rate of 30° C./s or more to 500° C./s or less, or that the silicon wafer is held at a temperature of 1020° C. or more to less than 1250° C. for 7 s or more to 600 s or less under an oxygen atmosphere and then the temperature is lowered at a rate of 1° C./s or more to 280° C./s or less.

It should be noted that the heat treatment is a second heat treatment performed after a first heat treatment in which a silicon wafer is subjected to a heat treatment at a maximum temperature reached of 1250° C. or more to a melting point or less, and, in the second heat treatment, the silicon wafer is desirably kept at the maximum temperature reached or less in the first heat treatment.

According to the method, when there is contamination with a metal that does not affect the lifetime as a single atom by itself, in the heat treatment, the treatment of holding the silicon wafer at a temperature from 1250° C. or more to 1330° C. or less for 7 s to 220 s under an oxygen atmosphere, and then, lowering the temperature at a rate from 30° C./s to 500° C./s is performed. Thereby, point defects (atomic vacancies) in the wafer and metal atoms are combined to become compound defects and the lifetime reduction is promoted.

Accordingly, when the lifetime measurement is performed by the μ-PCD method on the silicon wafer, the lifetime measurement can be performed with higher sensitivity.

In addition, when there is metal contamination that affects the lifetime as atoms themselves, in the heat treatment, the treatment of holding the silicon wafer at a temperature of 1020° C. or more to less than 1250° C. for 7 s or more to 600 s or less under an oxygen atmosphere and then lowering the temperature at a rate of 1° C./s or more to 280° C./s or less is performed, and thereby, unnecessary crystal defects that are noise in the lifetime measurement can be significantly reduced.

Accordingly, when the lifetime measurement is performed by the μ-PCD method on the silicon wafer, the lifetime measurement can be performed with higher sensitivity.

Furthermore, after the above lifetime measurement, it is desirable to obtain the lifetime due to crystal characteristic factors from the correlation between the resistivity and the lifetime of a silicon wafer without metal contamination, but with only resistivity due to the crystal characteristic factors, and to obtain a corrected lifetime corresponding to the desired resistivity from which the influence of the resistivity due to the crystal characteristic factors is eliminated using the following expression:

Corrected lifetime=Lifetime due to the crystal characteristic factors with the desired resistivity+Lifetime measurement value−Lifetime due to the crystal characteristic factors of the measurement sample.

In addition, it is desirable to obtain the lifetime due to the crystal characteristic factors using the following expression:

Lifetime due to the crystal characteristic factors=A×resistivity+B,

where A is a coefficient and B is a constant.

Alternatively, the lifetime due to the crystal characteristic factors can be obtained using the following expression:

Lifetime due to the crystal characteristic factors=C×(resistivity)⁶+D×(resistivity)⁵+E×(resistivity)⁴+F×(resistivity)³+G×(resistivity)²+H×resistivity+I,

where C, D, E, F, G, H are coefficients and I is a constant.

As described above, the correlation expression between the lifetime and the resistivity without metal contamination is obtained, and the measured lifetime is corrected to a value obtained by excluding a part dependent on the resistivity due to the crystal characteristic factors from the measured lifetime based on the correlation expression, and thereby, the lifetime management, i.e., the metal contamination evaluation of the silicon wafer products different in resistivity, can be easily performed.

### Advantageous Effects of Invention

According to the present invention, an amount of metal contamination on a silicon wafer can be evaluated with higher accuracy by lifetime measurement.

### BRIEF DESCRIPTION OF DRAWINGS

FIG. 1 shows a flowchart of a first embodiment of an evaluation method of metal contamination of the present invention.

FIG. 2 shows a flowchart of a second embodiment of the evaluation method of metal contamination of the present invention.

FIG. 3 is a graph showing a relationship between the lifetime of a silicon wafer product lot having a resistivity of 32 to 46 Ω·cm and resistivity in an example.

FIG. 4 is a graph of the plot of the data obtained by correcting the population data of the lifetimes using a correlation expression between the lifetime and the resistivity in the example.

FIG. 5 is a graph of the plot of the inspection data of a product lot at the same standard as the population data in FIG. 3.

FIG. 6 is a graph showing the application of the resistivity correction and the upper and lower control limit to the data in FIG. 5.

FIG. 7 is a graph showing the relationships between the lifetimes of a silicon wafer product lot having a resistivity of 27 to 59 Ω·cm and the resistivity in an example.

FIG. 8 is a graph of the plot of the data obtained by correcting the population data of the lifetimes using a correlation expression between the lifetime and the resistivity in the example.

FIG. 9 is a graph of the plot of the inspection data of one product lot at the same standard as the population data in FIG. 7.

FIG. 10 is a graph showing the application of the resistivity correction and the upper and lower control limit to the data in FIG. 9.

FIG. 11 is a graph showing the application of a correlation expression by a polynomial approximation to the population data in FIG. 7.

FIG. 12 is a graph showing the application of the resistivity correction using a polynomial approximation expression and the upper and lower control limit to the data in FIG. 11.

FIG. 13 is a graph of the plot of the lifetimes corrected by the correlation expression 10.

### DESCRIPTION OF EMBODIMENTS

An evaluation method of metal contamination according to the invention will be explained as follows. The evaluation method of metal contamination according to the invention is, for example, a method of evaluating metal contamination of a silicon wafer having a surface on which an oxide film (RTO film) is formed by heat treatment by a rapid thermal processing apparatus (hereinafter, also referred to as “RTP apparatus”) using lifetime measurement.

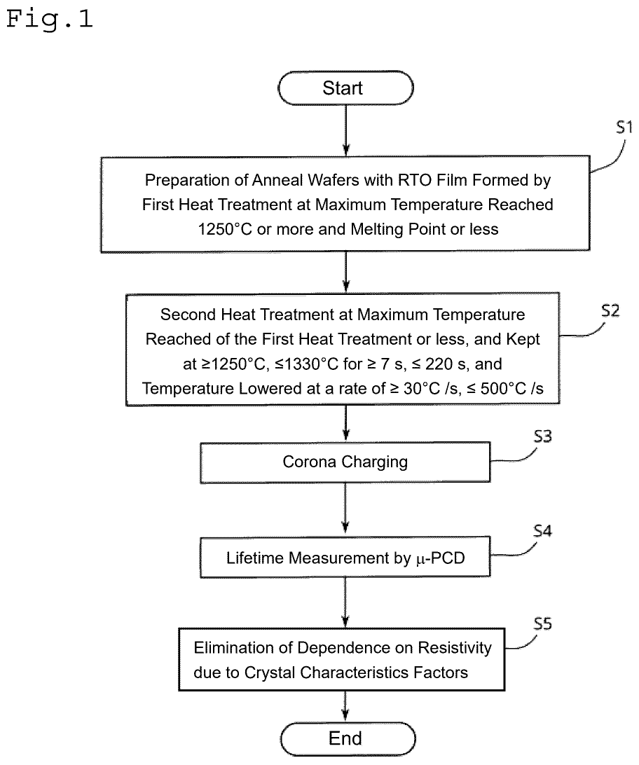

A first embodiment of the invention will be described along the flowchart shown in FIG. 1.

First, a silicon wafer having a surface on which an RTO film is formed (also referred to as an “anneal wafer”) is prepared (step S1 in FIG. 1). The anneal wafer is formed by a first heat treatment in the RTP apparatus on a silicon wafer sliced from a silicon single crystal. Specifically, the silicon wafer is held at the maximum temperature reached of 1250° C. or more to the melting point (e.g., 1300° C.) or lower for 1 s to 60 s under an oxygen atmosphere and the temperature thereof is lowered at 5° C./s to 150° C./s, and thereby forming an oxide film (RTO film) having a thickness of 2 nm or more on the silicon wafer.

The outward diffusion of metal impurities existing in members forming the apparatus is promoted by using the RPT apparatus at a higher temperature, thereby transferring the metal impurities in the furnace to a wafer.

Here, in the first embodiment, it is assumed that, in the metal contamination of the silicon wafer, there is contamination by a metal that does not affect the lifetime as a single atom itself.

Then, a second heat treatment is performed to the silicon wafer having the RTO film formed thereon in the RTP apparatus for reforming the RTO film (step S2 in FIG. 1).

Specifically, the wafer is held at a temperature of not more than the temperature of the first heat treatment of 1250° C. or more to 1330° C. or lower, preferably a temperature of 1250° C. or higher to 1320° C. or lower for 7 s or more to 220 s or less, preferably 8 s or more to 200 s or less under an oxygen atmosphere. The temperature of the wafer is then lowered at a rate of 30° C./s or more to 500° C./s or less, preferably of 50° C./s or more to 400° C./s or less.

The second heat treatment causes the point defects (atomic vacancies) generated during the first heat treatment and metal atoms, even contaminant metals that as a single atom itself do not affect the lifetime measurement to combine to change into complex defects which are in a state that affects the wafer resistivity. Further, the heat treatment temperature in the second heat treatment is set to be not more than the first heat treatment temperature, thereby, minimizing the property change with the second heat treatment.

Then, a passivation treatment by corona charging is applied to the silicon wafer after the second heat treatment (step S3 in FIG. 1). Specifically, ions generated by corona discharge are deposited on the RTO film to confine the carriers near the interface between the oxide film and the silicon wafer to the bulk.

Further, the lifetime measurement is performed on the corona-charged silicon wafer by the μ-PCD method (step S4 in FIG. 1).

As a μ-PCD measurement apparatus, for example, LTA-2200 EP manufactured by KOBELCO Research Institute is used and the lifetime measurement is performed at a laser wavelength of 904 nm with an injected carrier quantity of 5×10¹³/cm³ at a pitch of 4 mm. In the μ-PCD method, excess carriers are generated by pulse irradiation of a silicon wafer with a laser beam and annihilated by recombination, and the silicon wafer returns to the original equilibrium state. The change in the excess carrier density is exponential to the resistivity of the irradiated region, and the reflected microwave power changes with the resistivity. A difference in reflected microwave power between before irradiation and immediately after irradiation of the beam pulse corresponds to a difference in resistivity, i.e., a difference in carrier density, and a lifetime is obtained from a change over time.

Here, as described above, since the second heat treatment causes the point defects (atomic vacancies) generated during the first heat treatment and contaminant metal atoms, which are as atoms themselves do not affect the lifetime measurement, to combine to change into complex defects which are in a state that affects the wafer resistivity, the contaminant metals are detected by the lifetime measurement.

Further, the obtained lifetime is corrected to an equivalent value to the desired resistivity (e.g., 40 Ω·cm) (step S5 in FIG. 1). The correction is performed based on a correlation expression between the resistivity and the lifetime of the silicon wafer.

Specifically, first, the lifetime values for resistivity are measured in units of lots on silicon wafers unaffected by metal contamination. Expression 1 expressing a correlation between the lifetime and the resistivity is obtained based on the obtained lifetimes and population data of resistivity (all measurement data unaffected by metal contamination). Then, using Expression 1 and the resistivity to be managed, the lifetime of the silicon wafer to be managed is corrected to that in which the dependence of crystal characteristic factors on resistivity is excluded, based on the following Expression 2.

Correlation Expressions

Lifetime due to the crystal characteristic factors (affected only by resistivity due to the crystal characteristic factors)=A×resistivity+B Expression 1.

Lifetime after correction=(A×desired resistivity+B)+lifetime measurement value−(A×resistivity of measurement sample+B) Expression 2.

Note that the values of the coefficient A and the constant B may change depending on the crystal characteristics and heat treatment conditions.

Alternatively, in order to reduce variations of the lifetime, the lifetime may be obtained by the following polynomial Expression 3.

Lifetime due to the crystal characteristic factors (affected only by resistivity due to the crystal characteristic factors)=C×(resistivity)⁶+D×(resistivity)⁵+E×(resistivity)⁴+F×(resistivity)³+G×(resistivity)²+H×resistivity+I Expression 3.

Note that the values of the coefficients C, D, E, F, G, and H and the constant I change depending on the crystal characteristics and the heat treatment conditions.

In this case, the corrected lifetime is expressed by the following Expression 4.

Lifetime after correction=(C×(desired resistivity)⁶+D×(desired resistivity)⁵+E×(desired resistivity)⁴+F×(desired resistivity)³+G×(desired resistivity)²+H×desired resistivity+I)+lifetime measurement value−(C×(resistivity of measurement sample)⁶+D×(resistivity of measurement sample)⁵+E×(resistivity of measurement sample)⁴+F×(resistivity of measurement sample)³+G×(resistivity of measurement sample)²+H×resistivity of measurement sample+I). Expression 4

As described above, according to the first embodiment of the invention, the RTO film is adjusted by the second heat treatment on the silicon wafer (anneal wafer) having the surface with the RTO film formed thereon by the first heat treatment with contamination by the metal that does not affect the lifetime as a single atom itself at a temperature lower than the maximum attainment temperature in the first heat treatment. That is, by the second heat treatment, the point defects (atomic vacancies) generated at the first heat treatment and metal atoms are combined to change to complex defects, and the lifetime reduction is promoted.

Thereby, when the lifetime measurement using the μ-PCD method is performed on the silicon wafer with the RTO film formed thereon, the lifetime measurement may be performed with higher sensitivity.

Further, the correlation expression between the lifetime and the resistivity is obtained and the measured lifetime is corrected to a lifetime value obtained by excluding a component dependent on the resistivity due to the crystal characteristic factors from the measured lifetime based on the correlation expression, and thereby, the lifetime management, i.e., the metal contamination evaluation of the silicon wafer products different in resistivity can be easily performed.

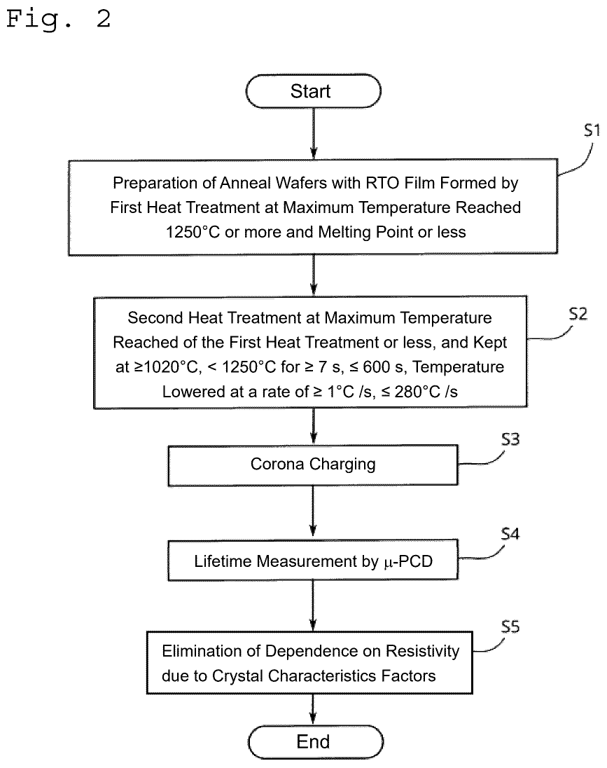

Subsequently, a second embodiment of the present invention will be described along a flow shown in FIG. 2.

First, a silicon wafer on the surface of which an RTO film is formed (also referred to as “anneal wafer”) is prepared (step S1 in FIG. 2). The anneal wafer is the silicon wafer that is sliced from a silicon single crystal and subjected to the first heat treatment in the RTP apparatus. Specifically, the silicon wafer is held at the maximum temperature reached from 1250° C. to the melting point (e.g., 1300° C.) for 1 s to 60 s under an oxygen atmosphere and the temperature thereof is lowered at a rate of 5° C./s to 150° C./s, thereby forming an oxide film (RTO film) having a thickness of 2 nm or more on the silicon wafer.

The RTP apparatus is used at a higher temperature to promote the outward diffusion of metal impurities present in members forming the apparatus. Thus, metal impurities in the furnace are transferred to a wafer.

Here, the contamination of the silicon wafer in the second embodiment is only contamination by a metal that affects the lifetime, as a single atom itself.

Then, the silicon wafer with the RTO film formed thereon is subjected to the second heat treatment in the RTP apparatus to modify the RTO film (step S2 in FIG. 2). Specifically, the wafer is held at a temperature not more than the temperature of the first heat treatment from 1020° C. to less than 1250° C., preferably from 1030° C. to less than 1250° C. for 7 s to 600 s, preferably for 8 s to 500 s, under an oxygen atmosphere. Then, the temperature of the wafer is lowered at a rate from 1° C./s to 280° C./s, preferably from 5° C./s to 250° C./s.

The second heat treatment significantly reduces undesired crystal defects that may cause noise in the subsequent lifetime measurements. In addition, the heat treatment temperature in the second heat treatment is set to be no higher than the first heat treatment temperature, thereby minimizing the property change with the second heat treatment.

Then, passivation treatment by corona charging is performed on the silicon wafer after the second heat treatment (step S3 in FIG. 2). Specifically, ions generated by corona discharge are deposited on the RTO film and the carriers near the interface between the oxide film and the silicon wafer are confined to the bulk.

Further, the lifetime of the corona-charged silicon wafer is measured by the μ-PCD method (step S4 in FIG. 2).

The μ-PCD measurement apparatus, e.g. LTA-2200 EP, manufactured by KOBELCO Research Institute is used and the lifetime measurement is performed at a laser wavelength of 904 nm with a number of injected carriers of 5×101³/cm³ with a pitch of 4 mm. In the μ-PCD method, excess carriers are generated by pulse irradiation of a silicon wafer with a laser beam and annihilated by recombination, and the silicon wafer returns to the original equilibrium state. The change in excess carrier density is an exponential change in the resistivity of the irradiated region, and the reflected microwave power changes accordingly. A difference in reflected microwave power between before irradiation and immediately after irradiation of the beam pulse corresponds to a difference in resistivity, i.e., a difference in carrier density, and a lifetime is obtained from a change over time.

Here, as described above, the second heat treatment significantly reduces the undesired crystal defects that cause noise in the subsequent lifetime measurement, and the lifetime measurement is performed with high accuracy.

Furthermore, the obtained lifetime is corrected to a value corresponding to a desired resistivity (e.g., 40 Ω·cm) (step S5 in FIG. 2). The correction is performed based on a correlation expression between the resistivity and the lifetime of the silicon wafer.

Specifically, first, the lifetime values for resistivity are measured by lot on silicon wafers unaffected by metal contamination. Expression 1 which expresses a correlation between the lifetime and the resistivity is obtained based on the obtained lifetime and resistivity population data (all measurement data unaffected by metal contamination). Then, from Expression 1 and the resistivity desired to be managed, the lifetime of the silicon wafer as an object to be managed is corrected to a lifetime excluding the resistivity dependence due to crystal characteristic factors based on the following Expression 2.

Correlation Expressions

Lifetime due to crystal characteristic factors (affected only by resistivity due to crystal characteristic factors)=A×resistivity+B. Expression 1

Corrected lifetime=(A×desired resistivity+B)+lifetime measurement value−(A×resistivity of measurement sample+B) Expression 2

Note that the values of the coefficient A and the constant B change depending on the crystal characteristics and the heat treatment conditions.

Alternatively, in order to reduce the variations of the lifetime, the lifetime due to crystal characteristic factors may be obtained by the following Polynomial Expression 3.

Lifetime due to crystal characteristic factors=C×(resistivity)⁶+D×(resistivity)⁵+E×(resistivity)⁴+F×(resistivity)³+G×(resistivity)²+H×resistivity+I. Expression 3

Note that the values of the coefficients C, D, E, F, G, and H and the constant I change depending on the crystal characteristics and the heat treatment conditions.

In this case, the corrected lifetime is expressed by the following Expression 4.

Corrected lifetime=(C×(desired resistivity)⁶+D×(desired resistivity)⁵+E×(desired resistivity)⁴+F×(desired resistivity)³+G×(desired resistivity)²+H×desired resistivity+I)+lifetime measurement value−(C×(resistivity of measurement sample)⁶+D×(resistivity of measurement sample)⁵+E×(resistivity of measurement sample)⁴+F×(resistivity of measurement sample)³+G×(resistivity of measurement sample)²+H×resistivity of measurement sample+I). Expression 4

As described above, according to the second embodiment of the invention, for silicon wafers (anneal wafers) with the RTO film formed on the surface by the first heat treatment and contamination with the metal that affects the lifetime as a single atom by itself, a second heat treatment at a lower temperature than the maximum temperature reached in the first heat treatment is applied to adjust the RTO film. That is, the second heat treatment significantly reduces the undesired crystal defects that cause noise in the lifetime measurement.

Therefore, by using the μ-PCD method is performed on the silicon wafer with the RTO film formed on it, the lifetime can be measured with high sensitivity.

Further, the correlation expression between the lifetime and the resistivity is obtained and the measured lifetime is corrected to a lifetime value obtained by excluding a part dependent on the resistivity due to crystal characteristic factors from the measured lifetime based on the correlation expression, and thereby, the lifetime management, i.e., the metal contamination evaluation of the silicon wafer products different in resistivity, can be easily performed.

Note that if it is difficult to determine in the silicon wafer to be measured whether there is contamination with a metal that does not affect the lifetime as a single atom by itself or there is contamination with a metal that does affect the lifetime as a single atom by itself, experiments may be conducted in advance to determine whether to apply the second heat treatment method recited in the first embodiment (referred to as “Condition 1”) or the second heat treatment method recited in the second embodiment (referred to as “Condition 2”).

In this case, samples of multiple silicon wafers (anneal wafers) are taken from a single lot, and reference measurement values are obtained by performing passivation by corona charge and the lifetime measurement on, for example, one-third of the samples. Then, the condition 1 is applied to another third of the samples and lifetime measurement is performed thereon, and the condition 2 is applied to the other third of the samples and lifetime measurement is performed thereon.

Then, whether the condition 1 or the condition 2 is applied to the lot from which the samples are taken can be determined depending on which of the measured lifetime value when condition 1 is applied or the measured lifetime value when condition 2 is applied changes significantly with respect to the reference measured value. In addition, if both the measured lifetime value when condition 1 is applied and the measured lifetime value when condition 2 is applied change significantly with respect to the reference measured value, both the condition 1 and the condition 2 can be applied. In this case, as the second heat treatment, samples of a plurality of silicon wafers (anneal wafers) are taken from the single lot and, for example, the condition 1 is applied to a half of the samples and the condition 2 is applied to the other half of the samples and lifetime measurement is performed on the respective samples.

Further, in the first embodiment and second embodiment described above, the first heat treatment on the silicon wafer is performed at the maximum temperature reached of 1250° C. or more to not more than the melting point, however, in the invention, the first heat treatment may be applied to a case at the maximum temperature reached of lower than 1250° C., not limited to the above temperature.

Furthermore, in the first embodiment and second embodiment described above, the silicon wafer to which the invention is applied is the anneal wafer with the RTO film formed thereon in advance, however, in the invention, the oxide film formed on the silicon wafer is not limited to the RTO film formed by the rapid thermal processing apparatus, but may be an oxide film formed by another thermal processing apparatus. Alternatively, the silicon wafer to which the invention is applied may be a silicon wafer without an oxide film formed thereon in advance.

### Examples

The evaluation method of metal contamination according to the invention will be further explained with reference to an example. In the example, the following experiments were performed based on the embodiments described above.

### (Experiment 1)

In Experiment 1, an n-type silicon wafer having a resistivity of 60 Ω·cm was used, and heat treatment (first heat treatment) was performed under oxygen atmospheres in a thermal processing apparatus with a higher metal contamination concentration and a thermal processing apparatus with a lower metal contamination concentration, respectively.

The thermal processing apparatus with the higher metal contamination concentration is a thermal processing apparatus in which the average lifetime within the wafer surface is less than 50% of a theoretical lifetime estimated from a dopant concentration (called ISRH value). On the other hand, the thermal processing apparatus with the lower metal contamination concentration is a thermal processing apparatus in which the average lifetime within the wafer surface is 50% or more of the TSRH value.

In this experiment, the following operations were performed to distinguish the thermal processing apparatus with the higher metal contamination concentration from the thermal processing apparatus with the lower metal contamination concentration.

First, a p-type silicon single crystal was grown at a pulling rate of 0.6 mm/min, with an oxygen concentration of 1.2×10¹³/cm³, with a resistivity of 36 Ω·cm, and with a dopant concentration of boron of 3.7×10¹⁴/cm³, and a silicon wafers were sliced from the center part of the silicon single crystal ingot with a total length of 1000 mm or more. Then, as a heat treatment condition in the thermal processing apparatus (RTP apparatus), the silicon wafer was held at 1350° C. for 30 s under an oxygen atmosphere and the temperature thereof was lowered to 600° C. at a temperature lowering rate of 120° C./s.

In this way, an RTO film was formed on the silicon wafer, and then, passivation was performed by corona charging, and lifetime measurement was performed by the μ-PCD apparatus.

Then, with the theoretical lifetime TSRH estimated from the dopant concentration as 3800 μs, if the measured average lifetime within the wafer surface was less than 50% (1900 μs) of TSRH (3800 μs), the thermal processing apparatus was determined to be a thermal processing apparatus with a higher metal contamination concentration, and if the value was 50% or more, the thermal processing apparatus was determined to be a thermal processing apparatus with a lower metal contamination concentration.

In the first heat treatment in Experiment 1, the n-type silicon wafer with a resistivity of 60 Ω·cm sliced from the silicon single crystal ingot was held at a temperature of 1300° C. or more to the melting point or less for 1 s to 60 s under an oxygen atmosphere and subjected to the temperature lowering process at a temperature lowering rate of 5° C./s to 150° C./s, and thereby forming an oxide film (RTO film) with a thickness of 2 nm or more on the silicon wafer.

The heat-treated silicon wafer was cleaned, and then, oxidation treatment (second heat treatment) and lifetime pretreatment were performed under the conditions shown in Table 1, and lifetime measurement was performed.

As the conditions of the second heat treatment, the heat treatment temperature (° C.), the heat treatment time (s), and the temperature lowering rate (° C./s) are shown in Table 1, and as the lifetime pretreatment method, either corona charging treatment or hydrofluoric acid treatment is shown therein.

In the corona charging treatment, on the silicon wafer with the RTO film formed thereon, ions generated by corona discharge were deposited on the oxide film (RTO film) using an optional function of a μ-PCD measurement apparatus (LTA-2200 EP manufactured by KOBELCO Research Institute), and carriers around the interface were confined to the bulk by the ions on the surface.

In the hydrofluoric acid treatment, the silicon wafer was placed in a carrier made of Teflon (registered trademark), and the carrier was immersed in a 10%-HF solution for 15 min, and then, moved to an overflow tank. The silicon wafer was then immersed in the overflow tank containing ultrapure water and rinsed for 10 minutes. Ultrapure water was poured into the overflow tank at a flow rate of 5 L/min and the silicon wafer was rinsed as the ultrapure water flowed out of the overflow tank, i.e., continuously with fresh ultrapure water.

Note that the ultrapure water used to prepare the 10% HF solution and the ultrapure water used for rinsing was ultrapure water with a resistivity of 18.2 MΩ·cm or more, containing total organic carbon (TOC) of 10 ppb or less, silica of less than 0.1 ppb, boron of 0.04 ppb, and metal elements of 10 ppt or less.

After rinsing, the silicon wafer was slowly pulled up from the overflow tank and the water was drained off, and the silicon wafer was dried. The surface of the silicon wafer has a hydrophobic property, and accordingly, the silicon wafer can be dried by slowly pulling it up from the overflow tank. Then, the surface of the silicon wafer was passivated with hydrofluoric acid.

Table 1 shows the measurement results of the cases with metal contamination (when the first heat treatment is performed using the thermal processing apparatus with the higher metal contamination concentration) and without metal contamination (when the first heat treatment is performed using the thermal processing apparatus with the lower metal contamination concentration) as the lifetime measurement results.

TABLE 1

| | | | Heat | | | | |
|---|---|---|---|---|---|---|---|
| | | | treatment | Formed | | | |
| | Heat | Heat | temperature | oxide | | Lifetime | Lifetime |
| | treatment | treatment | lowering | film | Lifetime | (with metal | (without metal |
| | temperature | time | rate | thickness | pretreatment | contamination) | contamination) |
| | (° C.) | (s) | (° C./s) | (nm) | method | (μs) | (μs) |
| Example 1-1 | 1250 | 10 | 100 | 11 | Corona | 4189 | 8833 |
| | | | | | charging | | |
| | | | | | treatment | | |
| Example 1-2 | 1300 | 10 | 100 | 15 | Corona | 4322 | 9432 |
| | | | | | charging | | |
| | | | | | treatment | | |
| Example 1-3 | 1250 | 120 | 100 | 39 | Corona | 4960 | 9078 |
| | | | | | charging | | |
| | | | | | treatment | | |
| Example 1-4 | 1300 | 120 | 100 | 51 | Corona | 4941 | 8621 |
| | | | | | charging | | |
| | | | | | treatment | | |
| Example 1-5 | 1250 | 10 | 300 | 11 | Corona | 4602 | 9305 |
| | | | | | charging | | |
| | | | | | treatment | | |
| Example 1-6 | 1300 | 10 | 300 | 15 | Corona | 4737 | 8559 |
| | | | | | charging | | |
| | | | | | treatment | | |
| Example 1-7 | 1250 | 120 | 300 | 39 | Corona | 4434 | 9026 |
| | | | | | charging | | |
| | | | | | treatment | | |
| Example 1-8 | 1300 | 120 | 300 | 51 | Corona | 4279 | 9152 |
| | | | | | charging | | |
| | | | | | treatment | | |
| Comparative | 1200 | 10 | 100 | 8 | Corona | 8796 | 8965 |
| Example 1-1 | | | | | charging | | |
| | | | | | treatment | | |
| Comparative | 1350 | 10 | 100 | 18 | Corona | 110 | 98 |
| Example 1-2 | | | | | charging | | |
| | | | | | treatment | | |
| Comparative | 1250 | 5 | 100 | 4 | Corona | 4840 | 5603 |
| Example 1-3 | | | | | charging | | |
| | | | | | treatment | | |
| Comparative | 1250 | 240 | 100 | 60 | Corona | 4686 | 7468 |
| Example 1-4 | | | | | charging | | |
| | | | | | treatment | | |
| Comparative | 1250 | 120 | 10 | 39 | Corona | 9313 | 8521 |
| Example 1-5 | | | | | charging | | |
| | | | | | treatment | | |
| Comparative | 1250 | 10 | 100 | 11 | Hydrofluoric | 2225 | 2026 |
| Example 1-6 | | | | | acid | | |
| | | | | | treatment | | |
| Comparative | 1300 | 10 | 100 | 15 | Hydrofluoric | 2076 | 2915 |
| Example 1-7 | | | | | acid | | |
| | | | | | treatment | | |

From the results of Experiment 1, it is found that under the conditions of Examples 1-1 to 1-8 (holding at the heat-treatment temperature of 1250° C. to 1300° C. for 10 s to 120 s, lowering the temperature at a rate of 100° C./s to 300° C./s), the lifetime is reduced in the presence of metal contamination. It is estimated that point defects (atomic vacancies) generated at the high-temperature heat treatment (second heat treatment) and metal atoms were combined and the lifetime reduction was promoted.

A silicon wafer with less metal contamination having a lifetime of 8000 μs or more was able to be specified.

On the other hand, in Comparative Example 1-1, it was found that the lifetime remained unchanged regardless of the presence or absence of metal contamination. It is speculated that because the heat treatment temperature in the second heat treatment was low and the generation of point defects was not sufficient, metal contamination was not detected.

In Comparative Example 1-2, it was found that the lifetime remained unchanged regardless of the presence or absence of metal contamination. It is speculated that the heat treatment temperature in the second heat treatment was high, the amount of generated point defects was excessive and the influence by the point defects become predominant, and metal contamination was not detected.

In Comparative Example 1-3, it was found that there was a slight difference in lifetime depending on the presence or absence of metal contamination. It is speculated that the corona charging was less effective due to the thinner oxide film and metal contamination is not sufficiently detected.

In Comparative Example 1-4, it was found that there was a slight difference in lifetime depending on the presence or absence of metal contamination. It is speculated that the corona charging was less effective due to the large thickness of the oxide film and metal contamination was not sufficiently detected.

In Comparative Example 1-5, it was found that there was a slight difference in lifetime depending on the presence or absence of metal contamination. It is speculated that the concentration of point defects left on the wafer was lowered due to the low temperature lowering rate and metal contamination was not sufficiently detected.

In Comparative Example 1-6 and Comparative Example 1-7, it was found that the lifetime remained unchanged regardless of the presence or absence of metal contamination. It is speculated that the passivation by hydrofluoric acid was less effective and metal contamination was not sufficiently detected.

### Experiment 2

In Experiment 2, an n-type silicon wafer with a resistivity of 60 Ω·cm was used and heat-treated (first heat treatment) under oxygen atmospheres in a thermal processing apparatus with a higher metal contamination concentration and a thermal processing apparatus with a lower metal contamination concentration, respectively.

The thermal processing apparatuses were different from those used in Experiment 1 in the contamination element. The definition of the thermal processing apparatus with the higher metal contamination concentration and with the lower metal contamination is the same as that in Experiment 1.

In the first heat treatment, the n-type silicon wafer with a resistivity of 60 Ω·cm sliced from the silicon single crystal was held at a temperature of 1300° C. or higher to the melting point or less for 1 s to 60 s under an oxygen atmosphere and the temperature thereof was lowered at a rate of 5° C./s to 150° C./s, and thereby forming an oxide film (RTO film) with a thickness of 2 nm or more on the silicon wafer.

The heat-treated silicon wafer was cleaned, and then, oxidation treatment (second heat treatment) and lifetime pretreatment were performed under the conditions shown in Table 2, and lifetime measurement was performed.

Table 2 shows, as the conditions of the second heat treatment, the heat treatment temperature (° C.), the heat treatment time (s), and the temperature lowering rate (° C./s), and for the lifetime pretreatment methods, either corona charging treatment or hydrofluoric acid treatment.

In the corona charging treatment, on the silicon wafer with the RTO film formed thereon similar to Experiment 1, ions generated by corona discharge were deposited on the oxide film (RTO film) using the μ-PCD measurement apparatus (LTA-2200 EP manufactured by KOBELCO Research Institute) and carriers around the interface were confined to the bulk.

Further, in the hydrofluoric acid treatment, the surface of the silicon wafer was passivated with hydrofluoric acid using a method similar to that of Experiment 1.

Table 2 shows the measurement results of the cases with metal contamination (when the first heat treatment is performed using the thermal processing apparatus with higher metal contamination concentration) and without metal contamination (when the first heat treatment is performed using the thermal processing apparatus with lower metal contamination concentration) as the lifetime measurement results.

TABLE 2

| | | | Heat | | | |
|---|---|---|---|---|---|---|
| | | | treatment | | | |
| | Heat | Heat | temperature | | Lifetime | Lifetime |
| | treatment | treatment | lowering | Lifetime | (with metal | (without metal |
| | temperature | time | rate | pretreatment | contamination) | contamination) |
| | (° C.) | (s) | (° C./s) | method | (μs) | (μs) |
| Example 2-1 | 1050 | 10 | 10 | Corona | 6242 | 10883 |
| | | | | charging | | |
| | | | | treatment | | |
| Example 2-2 | 1200 | 10 | 10 | Corona | 6268 | 10402 |
| | | | | charging | | |
| | | | | treatment | | |
| Example 2-3 | 1050 | 120 | 10 | Corona | 6812 | 10547 |
| | | | | charging | | |
| | | | | treatment | | |
| Example 2-4 | 1200 | 120 | 10 | Corona | 6799 | 10381 |
| | | | | charging | | |
| | | | | treatment | | |
| Example 2-5 | 1050 | 10 | 100 | Corona | 6496 | 10479 |
| | | | | charging | | |
| | | | | treatment | | |
| Example 2-6 | 1200 | 10 | 100 | Corona | 6572 | 10592 |
| | | | | charging | | |
| | | | | treatment | | |
| Example 2-7 | 1050 | 120 | 100 | Corona | 6186 | 10656 |
| | | | | charging | | |
| | | | | treatment | | |
| Example 2-8 | 1200 | 120 | 100 | Corona | 6285 | 10809 |
| | | | | charging | | |
| | | | | treatment | | |
| Example 2-9 | 1100 | 240 | 100 | Corona | 6638 | 10285 |
| | | | | charging | | |
| | | | | treatment | | |
| Comparative | 1000 | 10 | 100 | Corona | 936 | 262 |
| Example 2-1 | | | | charging | | |
| | | | | treatment | | |
| Comparative | 1250 | 10 | 100 | Corona | 6162 | 8630 |
| Example 2-2 | | | | charging | | |
| | | | | treatment | | |
| Comparative | 1100 | 5 | 100 | Corona | 2315 | 2404 |
| Example 2-3 | | | | charging | | |
| | | | | treatment | | |
| Comparative | 1200 | 120 | 300 | Corona | 6340 | 8990 |
| Example 2-4 | | | | charging | | |
| | | | | treatment | | |

From the results of Experiment 2, it was found that under the conditions of Examples 2-1 to 2-9 (held at the heat-treatment temperature of 1050° C. or more to less than 1250° C. for 10 s or more, the temperature was lowered at a rate of 10° C./s or more to 200° C./s or less), with metal contamination, the lifetime was reduced. It is speculated that point defects in the silicon wafer were eliminated by the second heat treatment, and the differences in lifetime depending on the presence or absence of metal contamination become clearer.

Meanwhile, in Comparative Example 2-1, it was found that the lifetime with metal contamination was longer than that without metal contamination. It is speculated that because the heat treatment temperature was low and crystal defects remained, the metal contamination was not sufficiently detected.

In Comparative Example 2-2, it was found that the lifetime remained unchanged regardless of the presence or absence of metal contamination. It is speculated that the difference in lifetime depending on the presence or absence of metal contamination was not greater due to the generation of defects in the heat treatment (second heat treatment).

In Comparative Example 2-3, it was found that the lifetime remained unchanged regardless of the presence or absence of metal contamination. It is speculated that because the heat treatment time of the second heat treatment was shorter and crystal defects remained, metal contamination was not sufficiently detected.

In Comparative Example 2-4, it was found that there was a slight difference in lifetime depending on the presence or absence of metal contamination. It is speculated that because the temperature-lowering rate of the heat treatment in the second heat treatment was high and the crystal defects remained, metal contamination was not sufficiently detected.

### Experiment 3

The lifetime of the silicon wafer depends on the resistivity. Accordingly, in Experiment 3, it was verified whether the influence of resistivity due to crystal characteristic factors can be eliminated by correcting the lifetime corresponding to a certain resistivity. If the influence of resistivity due to crystal characteristic factors can be eliminated in the lifetime measurement, a lifetime measurement value can be obtained that is affected only by the influence of resistivity due to metal contamination.

### Experiment 3-1

In Experiment 3-1, a relationship between lifetime and resistivity was first obtained for a silicon wafer from a product lot that has no metal contamination but has a resistivity of 32 to 46 Ω·cm due to crystal characteristic factors. The lifetime was measured by the μ-PCD method after corona charging the silicon wafer. In a graph of FIG. 3, the relationships between resistivity and the measured lifetimes were plotted. In FIG. 3, the vertical axis indicates the lifetime (μs) and the horizontal axis indicates the resistivity (Ω·cm). A correlation expression between the lifetime and the resistivity obtained on the basis of population data of lifetimes and resistivity (all measurement data unaffected by metal contamination) is given by the following expression 5.

Correlation Expressions

Lifetime due to crystal characteristic factors (affected only by resistivity due to crystal characteristic factors)=248.6×resistivity−2596.2. Expression 5

Using the correlation expression 5, a lifetime value obtained by eliminating the resistivity dependence due to crystal characteristic factors and correcting to a value corresponding to the desired resistivity (corrected lifetime) can be calculated by the following expression 6.

Corrected lifetime=(248.6×desired resistivity+2596.2)+lifetime measurement value−(248.6×resistivity of measurement sample−2596.2). Expression 6

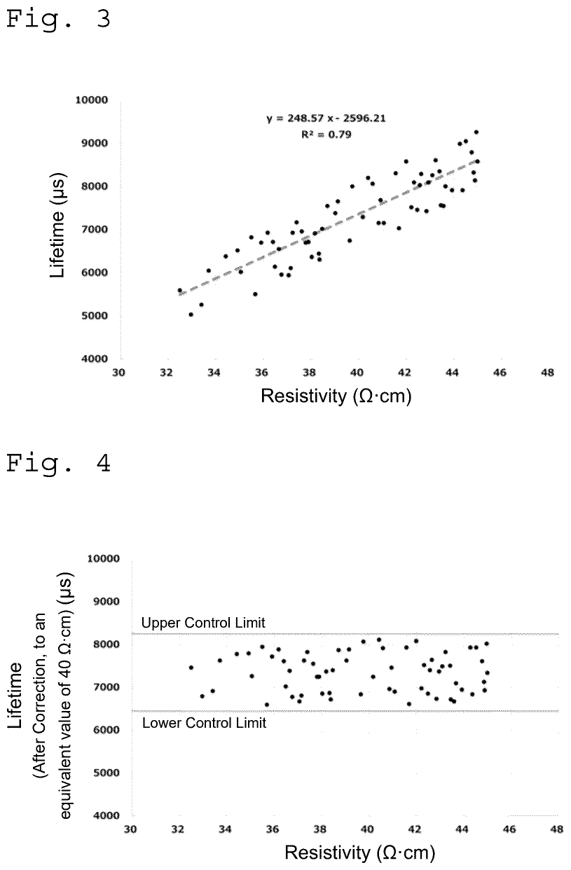

The data obtained by correcting the lifetime measurement data using expression 6 were plotted on a graph of FIG. 4. In FIG. 4, the vertical axis indicates the lifetime (μs) and the horizontal axis indicates the resistivity (Ω·cm). The graph in FIG. 4 shows the variation of the lifetime in the measurement lot. For example, if a control value is set by one time of the standard deviation, an upper control limit (8248.3 μs) and a lower control limit (6444.9 μs) can be set as shown in FIG. 4.

### Experiment 3-2

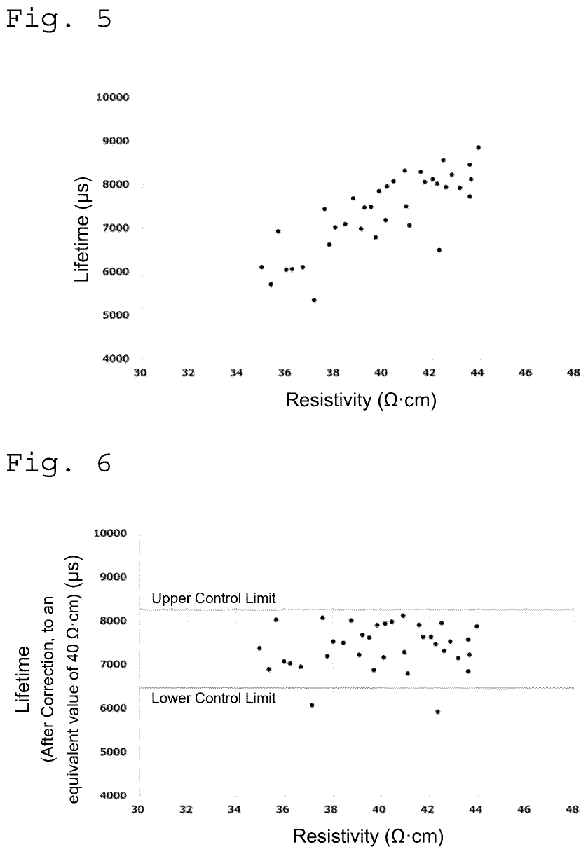

In Experiment 3-2, lifetimes were measured using a product lot at the same standard (resistivity from 32 to 46 Ω·cm) as the silicon wafer used in Experiment 3-1 under the same conditions as those of Experiment 3-1. The relationships between the resistivity and the measured lifetimes were plotted on a graph of FIG. 5. In FIG. 5, the vertical axis indicates the lifetime (μs) and the horizontal axis indicates the resistivity (Ω·cm).

Then, corrected lifetimes were calculated using expression 6 obtained in Experiment 3-1. The corrected lifetimes were obtained by eliminating the influence of resistivity due to crystal characteristic factors.

The corrected lifetimes were plotted on a graph of FIG. 6. In FIG. 6, the vertical axis indicates the lifetime (μs) and the horizontal axis indicates the resistivity (Ω·cm).

Here, applying the upper control limit (8248.3 μs) and the lower control limit (6444.9 μs) set in Experiment 3-1 to the graph in FIG. 6, it was found that two products (non-conforming products) were outside the range of control values.

From these results, it was confirmed that by correcting with the lifetime equivalent to a certain specific resistivity, the influence of resistivity due to crystal characteristic factors can be eliminated, and the lifetime management of products with different resistivities can be facilitated.

### Experiment 4

### Experiment 4-1

In Experiment 4-1, a relationship between lifetime and resistivity was first obtained for a silicon wafer from a silicon wafer product lot that has no metal contamination but has a resistivity of 27 to 59 Ω·cm due to crystal characteristic factors. The lifetime measurement was performed in the same manner as that in Experiment 3-1.

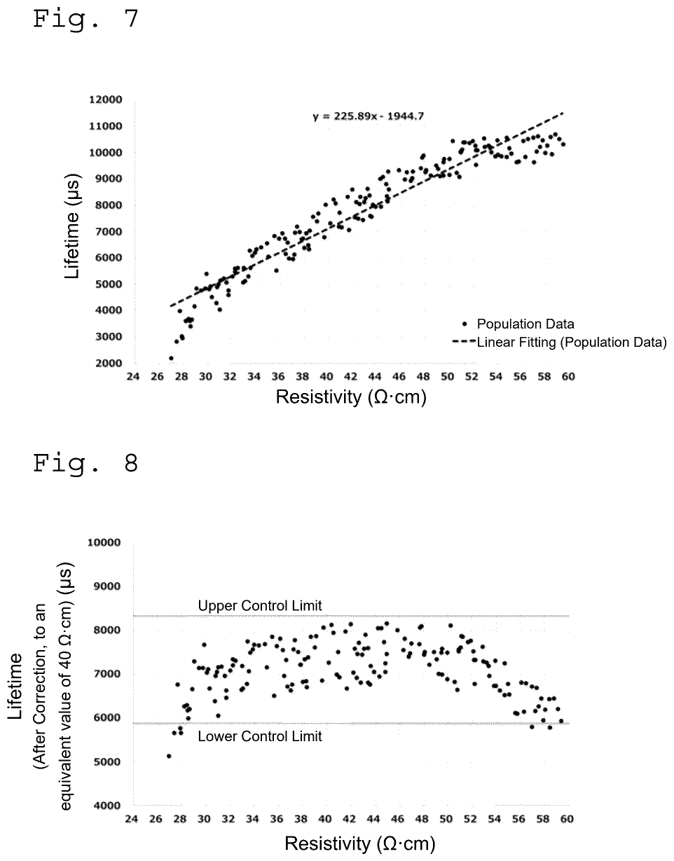

The relationships between the resistivity and the measured lifetimes were plotted on a graph of FIG. 7. In FIG. 7, the vertical axis indicates the lifetime (μs) and the horizontal axis indicates the resistivity (Ω·cm). A correlation expression between lifetime and resistivity obtained on the basis of population data of lifetime and resistivity (all measurement data unaffected by metal contamination) was given by the following expression 7.

Correlation Expression

Lifetime due to crystal characteristic factors (affected only by resistivity due to crystal characteristic factors)=225.9×resistivity−1944.7 Expression 7

Using the correlation expression 7, a lifetime value obtained by eliminating the resistivity dependence due to crystal characteristic factors and correcting to a value corresponding to the desired resistivity (corrected lifetime) can be calculated as the following expression 8.

Corrected lifetime=(225.9×desired resistivity−1944.7)+(lifetime measurement value)−(225.9×resistivity of measurement sample−1944.7). Expression 8

The data obtained by correcting the lifetime measurement data using expression 8 were plotted on a graph of FIG. 8. In FIG. 8, the vertical axis indicates the lifetime (μs) and the horizontal axis indicates the resistivity (Ω·cm). The graph in FIG. 8 shows the variation in the lifetime of the measurement lot. For example, when an upper control limit (8313.6 μs) and a lower control limit (5868.5 μs) were set as in Experiment 3-1, it was found that variations were large even when the population without metal contamination was used.

### Experiment 4-2

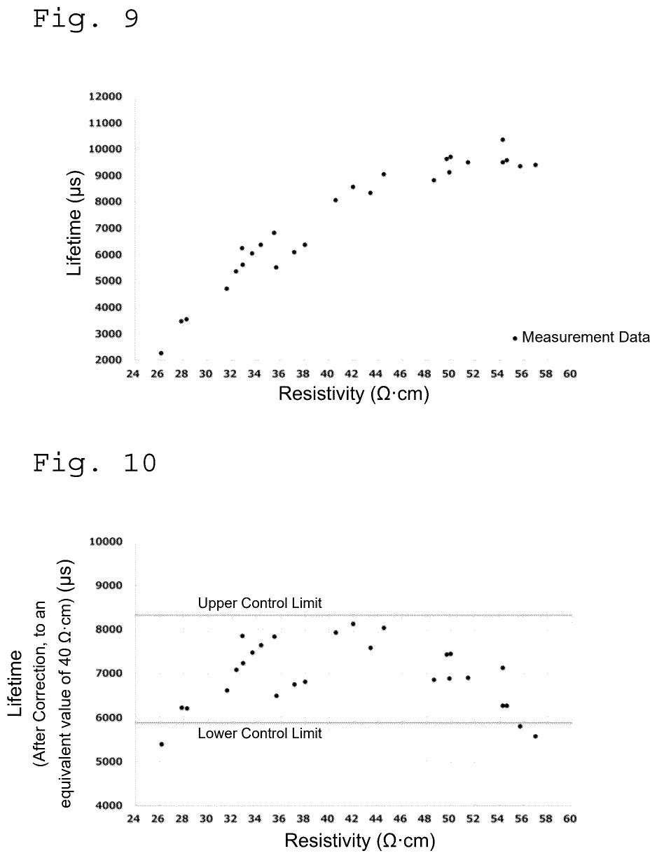

In Experiment 4-2, the lifetimes were measured using a product lot of the same standard (resistivity from 26 to 56 Ω·cm) as the silicon wafer used in Experiment 4-1 under the same conditions as in Experiment 4-1. In a graph of FIG. 9, the relationships between the resistivity and the measured lifetimes were plotted. In FIG. 9, the vertical axis indicates the lifetime (μs) and the horizontal axis indicates the resistivity (Ω·cm).

Corrected lifetimes were then calculated using expression 8 obtained in Experiment 4-1. The corrected lifetimes were obtained by eliminating the influence of resistivity due to crystal characteristic factors.

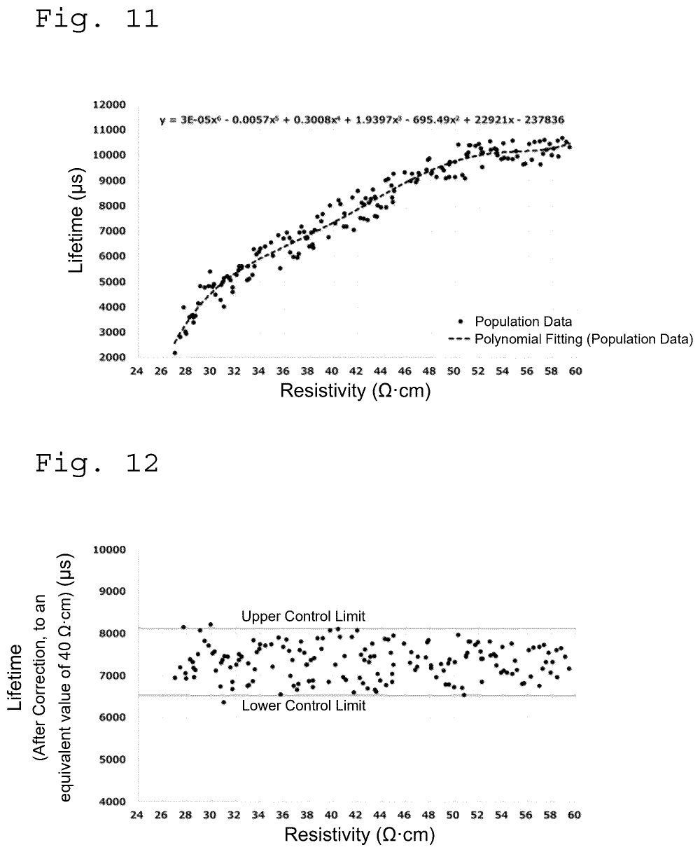

The corrected lifetimes were plotted on a graph in FIG. 10. In FIG. 10, the vertical axis indicates the lifetime (μs) and the horizontal axis indicates the resistivity (Ω·cm).

Here, when the upper control limit (8313.6 μs) and the lower control limit (5868.5 μs) set in Experiment 4-1 were applied to the graph of FIG. 10, it was found that there were three products (non-conforming products) outside the range of the control limit.

### Experiment 4-3

In Experiment 4-3, in FIG. 11, which plots the relationships between the resistivity in Experiment 4-1 and the measured lifetimes, a polynomial approximation correlation expression was obtained. In FIG. 11, the vertical axis indicates the lifetime (μs) and the horizontal axis indicates the resistivity (Ω·cm). A correlation expression between the lifetime and the resistivity obtained from the population data of lifetime and resistivity (all measurement data not affected by metal contamination) is the following expression 9.

Correlation Expression

Lifetime due to crystal characteristic factors (affected only by resistivity due to crystal characteristic factors)=3E-05×(resistivity)⁶−0.0057×(resistivity)⁵+0.3008×(resistivity)⁴+1.9397×(resistivity)³−695.49×(resistivity)²+22921×resistivity−237836. Expression 9

Using the Correlation Expression 9, a lifetime value obtained by excluding the resistivity dependence due to crystal characteristic factors and correcting a value corresponding to a desired resistivity (corrected lifetime) can be calculated as the following Expression 10.

Corrected lifetime=(3E-05×(desired resistivity)⁶−0.0057×(desired resistivity)⁵+0.3008×(desired resistivity)⁴+1.9397×(desired resistivity)³−695.49×(desired resistivity)²+22921×desired resistivity−237836)+(measured lifetime)−(3E-05×(measurement sample resistivity)⁶−0.0057×(measurement sample resistivity)⁵+0.3008×(measurement sample resistivity)⁴+1.9397×(measurement sample resistivity)³−695.49×(measurement sample resistivity)²+22921×measurement sample resistivity−237836). Expression 10

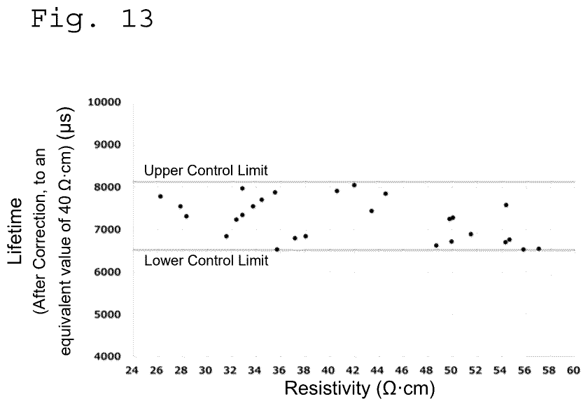

Data obtained by correction of the lifetime measurement data using Expression 10 were plotted on a graph of FIG. 12. In FIG. 12, the vertical axis indicates the lifetime (μs) and the horizontal axis indicates the resistivity (Ω·cm). The graph of FIG. 12 shows variations in the lifetime of the measurement lot. For example, an upper control limit (8119.8 μs) and a lower control limit (6513.8 μs) were set like those in Experiment 3-1, and thereby, it was found that variations were smaller than those in Experiment 4-1.

### Experiment 4-4

In Experiment 4-4, corrected lifetimes were calculated for the lifetimes measured in Experiment 4-2 using Expression 10 obtained in Experiment 4-3. The corrected lifetimes were obtained by eliminating the influence of resistivity due to crystal characteristic factors.

In the graph of FIG. 13, the corrected lifetimes have been plotted. In FIG. 13, the vertical axis indicates the lifetime (μs) and the horizontal axis indicates the resistivity (Ω·cm).

Here, the upper control limit (8119.8 μs) and the lower control limit (6513.8 μs) set in Experiment 4-3 were applied to the graph of FIG. 13; there was no product out of the management value range (nonconforming product).

These results confirm that lifetime correction corresponding to the specific value of resistivity can eliminate the influence of resistivity due to crystal characteristic factors and can facilitate the lifetime management of products with different resistivity.

What is claimed is:

1. A method of evaluating metal contamination of a silicon wafer, in which the silicon wafer is subjected to a heat treatment and further to a corona charge as passivation, and then the lifetime is measured,
wherein
the heat treatment is at least one of the treatment processes
that the silicon wafer is kept at a temperature of 1250° C. or more to 1330° C. or less for 7 s or more to 220 s or less under an oxygen atmosphere, and then the temperature is lowered at a rate of 30° C./s or more to 500° C./s or less, or
that the silicon wafer is kept at a temperature of 1020° C. or more to less than 1250° C. for 7 s or more to 600 s or less under an oxygen atmosphere, and then the temperature is lowered at a rate from 1° C./s re more to 280° C./s or less.

2. The method of evaluating metal contamination according to claim 1,
wherein
the heat treatment is a second heat treatment performed after a first heat treatment in which the silicon wafer is subjected to a heat treatment at a maximum temperature reached of 1250° C. or more to a melting point or less, and
in the second heat treatment, the silicon wafer is kept at the maximum temperature reached in the first heat treatment or less.

3. The method of evaluating metal contamination according to claim 2, further comprising:
after the lifetime measurement,
obtaining a lifetime due to crystal characteristic factors from a correlation between resistivity and the lifetime of a silicon wafer without metal contamination, but with only resistivity due to crystal characteristic factors; and
obtaining a corrected lifetime corresponding to a desired resistivity from which an influence of resistivity due to crystal characteristic factors is eliminated using the following expression:
Corrected lifetime=Lifetime due to crystal characteristic factors with desired resistivity+Lifetime measurement value−Lifetime due to crystal characteristic factors of a measurement sample.

4. The method of evaluating metal contamination according to claim 3, wherein
the lifetime due to crystal characteristic factors is obtained using the following expression:
Lifetime due to crystal characteristic factors=A×resistivity+B,
where A is a coefficient and B is a constant.

5. The method of evaluating metal contamination according to claim 3, wherein
the lifetime due to crystal characteristic factors is obtained using the following expression:
Lifetime due to crystal characteristic factors=C×(resistivity)⁶+D×(resistivity)⁵+E×(resistivity)⁴+F×(resistivity)³+G×(resistivity)²+H×resistivity+I,
where C, D, E, F, G, H are coefficients and I is a constant.
